(19) United States
(12) Patent Application Publication
(10) Pub. No.: US 2025/0210682 A1
(43) Pub. Date: Jun. 26, 2025

(54) CELL MONITORING DEVICE FOR A FUEL CELL

(71) Applicants: HYUNDAI MOTOR COMPANY, Seoul (KR); KIA CORPORATION, Seoul (KR)

(72) Inventor: Hyeon Jeong Park, Yongin-si (KR)

(73) Assignees: HYUNDAI MOTOR COMPANY, Seoul (KR); KIA CORPORATION, Seoul (KR)

(21) Appl. No.: 18/812,501

(22) Filed: Aug. 22, 2024

(30) Foreign Application Priority Data
Dec. 26, 2023 (KR) 10-2023-0191608

(51) Int. Cl. H01M 8/2475; H01M 8/04537

(52) U.S. Cl. CPC H01M 8/2475; H01M 8/04552

(57) ABSTRACT

A cell monitoring device for a fuel cell is mounted to a plurality of unit cells stacked in a first direction. The cell monitoring device includes a support part fitted and fixed to tabs protruding in a second direction, intersecting the first direction, from separators included in each of the plurality of unit cells and includes a connector coupled to the tabs while being supported by the support part. The support part includes a body fitted and fixed to portions of upper sides or lower sides of the tabs and includes a plurality of partition walls that extend from the body in a third direction, intersecting each of the first and second directions, to define spaces in which other portions of the tabs are disposed and are arranged in the same direction as a direction in which the separators are arranged.

### RELATED APPLICATION DATA

This application claims the benefit of and priority to Korean Patent Application No. 10-2023-0191608, filed on Dec. 26, 2023, which is hereby incorporated by reference as if fully set forth herein.

### BACKGROUND

### Field of the Disclosure

The present disclosure relates to a cell monitoring device for a fuel cell.

### Discussion of the Related Art

A cell stack of a fuel cell may supply power to an external load. The power is generated through electrochemical reaction between air supplied to one surface of a polymer electrolyte membrane and hydrogen supplied to the opposite surface of the polymer electrolyte membrane.

A cell stack may have a structure in which hundreds of unit cells are stacked. When the unit cells operate normally during operation of the cell stack, the unit cells may form a predetermined magnitude of voltage. In this case, due to the characteristics of the fuel cell in which cells are stacked in series in order to increase a voltage, if any one of hundreds of cells fails to exhibit normal performance, the total output of the cell stack is lowered. If this phenomenon continues, operation of the cell stack needs to be stopped.

Therefore, in order to check whether each of the unit cells of the cell stack exhibits normal performance, a cell monitoring device checks the state of each of the unit cells and continuously monitors the performance of each of the unit cells during operation of the cell stack. To this end, the cell monitoring device may be electrically connected to the unit cells constituting the cell stack in order to check the voltage of each of the unit cells. Studies on various structures for electrical connection between the cell monitoring connector and the cell stack are being carried out.

### SUMMARY

Accordingly, embodiments are directed to a cell monitoring device for a fuel cell that substantially obviates one or more problems due to limitations and disadvantages of the related art.

Embodiments disclosed herein provide a cell monitoring device for a fuel cell, which has excellent productivity and assemblability.

However, the objects to be accomplished by the disclosed embodiments are not limited to the above-mentioned objects. Other objects not mentioned herein should be more clearly understood by those of ordinary skill in the art from the following description.

Additional advantages, objects, and features of the disclosure are set forth in part in the following description and in part should become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

According to an embodiment, a cell monitoring device for a fuel cell is mounted to a plurality of unit cells stacked in a first direction. The cell monitoring device may include a support part configured to be fitted and fixed to tabs protruding in a second direction intersecting the first direction from separators included in each of the plurality of unit cells. The cell monitoring device may also include a connector configured to be coupled to the tabs while being supported by the support part. The support part may include a body configured to be fitted and fixed to portions of upper sides or lower sides of the tabs and may include a plurality of partition walls, which extend from the body in a third direction intersecting each of the first and second directions to define spaces in which other portions of the tabs are disposed and are arranged in the same direction as a direction in which the separators are arranged.

In an example, the width of each of the plurality of partition walls in the second direction may gradually decrease with increasing distance from the body in the third direction.

In an example, the width of each of the plurality of partition walls in the second direction may be constant.

In an example, each of the plurality of partition walls may have a shape further protruding than the body toward the connector in the second direction.

In an example, the cell monitoring device may further include a cover disposed so as to surround the connector and coupled to the support part to fix the connector fitted to the tabs.

In an example, the cover may include a housing including a receiving hole formed therein so as to receive the connector, a first cover coupling portion disposed on a first inner side surface of the housing facing the tabs in the second direction to be coupled to the connector, and a second cover coupling portion disposed on a second inner side surface of the housing facing the support part in the first direction to be coupled to the support part.

In an example, the connector may include a connector coupling portion coupled to the first cover coupling portion in a fitting manner.

In an example, the connector coupling portion may include a first protruding portion protruding from the rear surface of the connector toward the first inner side surface of the housing. The first cover coupling portion may include a second protruding portion protruding from the first inner side surface of the housing toward the rear surface of the connector. An end portion of the first protruding portion and an end portion of the second protruding portion may be coupled to each other in a fitting manner.

In an example, the connector coupling portion may include a third protruding portion protruding from the rear surface of the connector toward the first inner side surface of the housing. The first cover coupling portion may include a first concave portion disposed on the first inner side surface of the housing to receive the third protruding portion.

In an example, the first cover coupling portion may include a fourth protruding portion disposed on the first inner side surface of the housing and protruding toward the rear surface of the connector. The connector coupling portion may include a second concave portion disposed on the rear surface of the connector to receive the fourth protruding portion.

In an example, the support part may include a support part coupling portion coupled to the second cover coupling portion in a fitting manner.

In an example, the support part coupling portion may include a fifth protruding portion protruding toward the second inner side surface of the housing. The second cover coupling portion may include a third concave portion receiving the fifth protruding portion.

In an example, the second cover coupling portion may include a sixth protruding portion disposed on the second inner side surface of the housing. The support part coupling portion may include a fourth concave portion receiving the sixth protruding portion.

In an example, the body may include a first surface including slots formed therein so as to allow portions of the tabs to be fitted thereinto, a second surface located opposite the first surface in the third direction, a third surface located between the first surface and the second surface, and a fourth surface located opposite the third surface in the first direction. The support part coupling portion may be disposed on an outer side of each of the third and fourth surfaces of the body.

In an example, the first surface may correspond to the top surface of the body and the second surface may correspond to the bottom surface of the body. Alternatively, the first surface may correspond to the bottom surface of the body and the second surface may correspond to the top surface of the body.

In an example, each of the slots may be located in the middle between two neighboring ones of the plurality of partition walls defining the spaces.

In an example, the cell monitoring device may further include a gasket protruding from each of both surfaces of each of the tabs in the first direction and spaced apart from each of the plurality of partition walls.

In an example, the housing of the cover may include: a first portion facing the rear surface of the connector in the second direction; a second portion extending in the second direction from one side of one of two ends of the first portion toward the separators; a third portion extending in the second direction from one side of the other of the two ends of the first portion toward the separators and located opposite the second portion in the first direction; and a fourth portion coupled to the first to third portions to define the receiving hole and disposed so as to face the upper side or the lower side of the connector in the third direction. The first to third portions may form an opening to expose a portion of the connector supported by the support part.

In an example, the housing may include first and second housings coupled to each other in the first direction to define the receiving hole. The first housing may include a first sub-portion facing the rear surface of the connector in the second direction, a second sub-portion extending in the second direction from one of two side portions of the first sub-portion toward the separators, and a third sub-portion coupled to the first sub-portion and the second sub-portion. The second housing may include a fourth sub-portion facing the rear surface of the connector in the second direction and having one side portion contacting the other of the two side portions of the first sub-portion. The second housing may also include a fifth sub-portion extending in the second direction from the other of two side portions of the fourth sub-portion toward the separators and facing the second sub-portion in the first direction. The second housing may also include a sixth sub-portion coupled to the fourth sub-portion and the fifth sub-portion. The first, second, fourth, and fifth sub-portions may form an opening exposing a portion of the connector supported by the support part.

In an example, an end portion of the third sub-portion and an end portion of the sixth sub-portion may be disposed so as to be interdigitated with, engaged with, or fitted to each other.

In an example, the cell monitoring device may be disposed in an enclosure included in the fuel cell.

It is to be understood that both the foregoing general description and the following detailed description of the present disclosure are by way of example and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiment(s) of the disclosure and, together with the description, serve to explain the technical concepts and principles of the disclosure. In the drawings:

FIG. 1 is a cross-sectional view of end plates and a cell stack of a fuel cell;

FIG. 2A is a partially assembled perspective view of a cell monitoring device according to an embodiment;

FIG. 2B is a further assembled perspective view of the cell monitoring device shown in FIG. 2A;

FIG. 2C is a front view of the cell monitoring device shown in FIGS. 2A and 2B;

FIG. 2D is a rear view of the cell monitoring device shown in FIG. 2C;

FIG. 2E is an enlarged perspective view of portion “A” of the cell monitoring device shown in FIG. 2B;

FIG. 3 is a side view of a separator and a gasket shown in FIGS. 2A-2D;

FIGS. 4A-4D are, respectively, a perspective view, a plan view, a front view, and a side view of two connectors according to the embodiment;

FIG. 5A is a perspective view of an embodiment of a support part shown in FIGS. 2A-2E;

FIG. 5B is a plan view of an embodiment of the support part shown in FIG. 5A;

FIG. 5C is a front view of an embodiment of the support part shown in FIG. 5A;

FIG. 5D is a side view of an embodiment of the support part shown in FIG. 5A;

FIGS. 6A and 6B are, respectively, a perspective view and a side view of a support part according to another embodiment;

FIGS. 7A and 7B are, respectively, a perspective view and a side view of a support part according to still another embodiment;

FIGS. 8A and 8B are, respectively, a partially coupled front view and a partial side perspective view of a tab and a support part shown in FIGS. 2A-2E;

FIG. 9 is a coupled rear perspective view of embodiments of a connector and a cover shown in FIGS. 2A-2E;

FIG. 10A is a partial perspective view of an embodiment of the cover shown in FIGS. 2A-2E;

FIG. 10B is a partial perspective view of an embodiment of the connector shown in FIGS. 2A-2E;

FIG. 10C is a partially coupled perspective view of embodiments of the connector and the cover shown in FIGS. 2A-2E;

FIG. 10D is a partially exploded perspective view of other embodiments of the connector and the cover shown in FIGS. 2A-2E;

FIGS. 11A-11D are, respectively, a perspective view, a plan view, a front view, and a side view of the cover shown in FIGS. 2A-2E;

FIGS. 12A and 12B are, respectively, an exploded perspective view and an exploded cross-sectional view of a support part and a cover according to another embodiment;

FIGS. 13A-13C are, respectively, a rear perspective view, a front perspective view, and a front view of a cell monitoring device according to another embodiment;

FIG. 14 is a perspective view of an embodiment of a cover included in the cell monitoring device shown in FIGS. 13A-13C;

FIGS. 15A-15D are perspective views for explaining a method of mounting the cell monitoring device for a fuel cell according to an embodiment; and

FIGS. 16A and 16B are, respectively, a perspective view and a side-sectional view of the fuel cell and the cell monitoring device according to the embodiment.

### DETAILED DESCRIPTION

The present disclosure is described more fully hereinafter with reference to the accompanying drawings, in which various embodiments are shown. The examples, however, may be embodied in many different forms and should not be construed as being limited to the embodiments set forth herein. Rather, these embodiments are provided so that this disclosure is more thorough and complete, and more fully conveys the scope of the disclosure to those of ordinary skill in the art.

When a component, device, element, or the like of the present disclosure is described as having a purpose or performing an operation, function, or the like, the component, device, or element should be considered herein as being “configured to” meet that purpose or perform that operation or function.

It should be understood that, when an element is referred to as being “on” or “under” another element, the element may be directly on/under the other element, or one or more intervening elements may also be present.

When an element is referred to as being “on” or “under”, “under the element” as well as “on the element” may be included based on the element.

In addition, relational terms, such as “first”, “second”, “on/upper part/above” and “under/lower part/below”, are used only to distinguish between one subject or element and another subject or element, without necessarily requiring or involving any physical or logical relationship or sequence between the subjects or elements.

Hereinafter, cell monitoring devices 100A and 100B for a fuel cell according to embodiments are described with reference to the accompanying drawings. The cell monitoring devices 100A and 100B is described using the Cartesian coordinate system (x-axis, y-axis, z-axis) for convenience of description, but may also be described using other coordinate systems. In the Cartesian coordinate system, the x-axis, the y-axis, and the z-axis are perpendicular to each other, but the embodiments are not limited thereto. In other words, the x-axis, the y-axis, and the z-axis may intersect each other obliquely. In the following description, the x-axis direction is referred to as a “first direction”, the y-axis direction is referred to as a “second direction”, and the z-axis direction is referred to as a “third direction” for convenience of description. The first to third directions may be perpendicular to each other or may intersect each other obliquely.

The cell monitoring devices 100A and 100B according to the embodiments are connected to a fuel cell. The fuel cell may be, for example, a polymer electrolyte membrane fuel cell or proton exchange membrane fuel cell (PEMFC), which has been studied most extensively as a power source for driving vehicles. However, the embodiments are not limited to any specific type of fuel cell.

The fuel cell may include end plates (pressing plates or compression plates) and a cell stack.

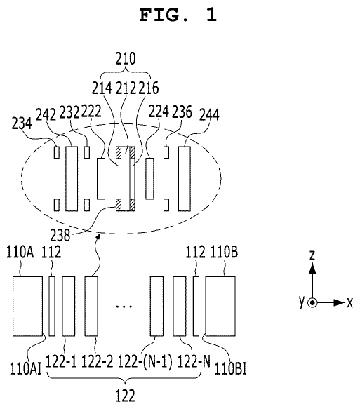

Hereinafter, an example of a cell stack is described with reference to FIG. 1. However, the embodiments are not limited to any specific type of cell stack.

FIG. 1 is a cross-sectional view of end plates and a cell stack of a fuel cell.

A cell stack 122 may include a plurality of unit cells 122-1 to 122-N, which are stacked in the first direction. Here, “N” is a positive integer of 1 or greater and may range from several tens to several hundreds. However, the embodiments are not limited to any specific value of “N”.

Each unit cell 122-n may generate electric power having a predetermined voltage. Here, 1≤n≤N. “N” may be determined depending on the intensity of the power to be supplied from the fuel cell to a load. Here, the load refers to a part of a vehicle that requires power when the fuel cell is used in the vehicle.

Each unit cell 122-n may include a membrane electrode assembly (MEA) 210, gas diffusion layers (GDLs) 222 and 224, gaskets 232, 234, and 236, and separators (or bipolar plates) 242 and 244.

The membrane electrode assembly 210 has a structure in which catalyst electrode layers, in which electrochemical reaction occurs, are attached to both sides of an electrolyte membrane through which hydrogen ions move. Specifically, the membrane electrode assembly 210 may include a polymer electrolyte membrane (or a proton exchange membrane) 212, a fuel electrode (a hydrogen electrode or an anode) 214, and an air electrode (an oxygen electrode or a cathode) 216. In addition, the membrane electrode assembly 210 may further include a sub-gasket 238.

The polymer electrolyte membrane 212 is disposed between the fuel electrode 214 and the air electrode 216.

Hydrogen, which is the fuel in the fuel cell, may be supplied to the fuel electrode 214 through the first separator 242. Air containing oxygen as an oxidizer may be supplied to the air electrode 216 through the second separator 244.

The hydrogen supplied to the fuel electrode 214 is decomposed into hydrogen ions (protons) (H+) and electrons (e−) by the catalyst. Only the hydrogen ions may be selectively transferred to the air electrode 216 through the polymer electrolyte membrane 212. At the same time, the electrons may be transferred to the air electrode 216 through the separators 242 and 244, which are conductors. In order to realize the above operation, a catalyst layer may be applied to each of the fuel electrode 214 and the air electrode 216. The movement of the electrons described above causes the electrons to flow through an external wire, thus generating current. That is to say, the fuel cell may generate power due to the electrochemical reaction between hydrogen, which is fuel, and oxygen contained in the air.

In the air electrode 216, the hydrogen ions supplied through the polymer electrolyte membrane 212 and the electrons transferred through the separators 242 and 244 meet oxygen in the air supplied to the air electrode 216. Thus, a reaction is caused that generates water (“condensed water” or “product water”).

In some cases, the fuel electrode 214 may be referred to as an anode and the air electrode 216 may be referred to as a cathode. Alternatively, the fuel electrode 214 may be referred to as a cathode and the air electrode 216 may be referred to as an anode.

The gas diffusion layers 222 and 224 serve to uniformly distribute hydrogen and oxygen, which are reactant gases, and to transfer the generated electrical energy. To this end, the gas diffusion layers 222 and 224 may be disposed on respective sides of the membrane electrode assembly 210. In other words, the first gas diffusion layer 222 may be disposed on the left side of the fuel electrode 214 and the second gas diffusion layer 224 may be disposed on the right side of the air electrode 216.

The first gas diffusion layer 222 may serve to diffuse and uniformly distribute hydrogen supplied as a reactant gas through the first separator 242 and may be electrically conductive. The second gas diffusion layer 224 may serve to diffuse and uniformly distribute air supplied as a reactant gas through the second separator 244 and may be electrically conductive.

Each of the first and second gas diffusion layers 222 and 224 may be a microporous layer in which fine carbon fibers are combined. However, the embodiments are not limited to any specific configuration of the first and second gas diffusion layers 222 and 224.

The gaskets 232, 234, and 236 may serve to maintain airtightness and clamping pressure of the cell stack at an appropriate level with respect to the reactant gases and the coolant, to disperse the stress when the separators 242 and 244 are stacked, and to independently seal the flow paths. As such, since airtightness and watertightness are maintained by the gaskets 232, 234, and 236, the flatness of the surfaces that are adjacent to the cell stack 122, which generates power, may be secured. Thus, surface pressure may be distributed uniformly over the reaction surface of the cell stack 122. To this end, the gaskets 232, 234, and 236 may be formed of rubber. However, the embodiments are not limited to any specific material of the gaskets.

The separators 242 and 244 may serve to move the reactant gases and the cooling medium and to separate each of the unit cells from the other unit cells. In addition, the separators 242 and 244 may serve to structurally support the membrane electrode assembly 210 and the gas diffusion layers 222 and 224 and to collect the generated current and transfer the collected current to current collectors 112.

The separators 242 and 244 may be disposed outside the gas diffusion layers 222 and 224, respectively. That is to say, the first separator 242 may be disposed on the left side of the first gas diffusion layer 222 and the second separator 244 may be disposed on the right side of the second gas diffusion layer 224.

The first separator 242 serves to supply hydrogen as a reactant gas to the fuel electrode 214 through the first gas diffusion layer 222. The second separator 244 serves to supply air as a reactant gas to the air electrode 216 through the second gas diffusion layer 224. In addition, each of the first and second separators 242 and 244 may form a channel through which a cooling medium (e.g. coolant) may flow. Further, the separators 242 and 244 may be formed of a graphite-based material, a composite graphite-based material, or a metal-based material. However, the embodiments are not limited to any specific material of the separators 242 and 244.

The end plates 110A and 110B shown in FIG. 1 may be disposed at the respective ends of the cell stack 122 and may support and fix the unit cells 122. In other words, the first end plate 110A may be disposed at one end of the cell stack 122 and the second end plate 110B may be disposed at the opposite end of the cell stack 122.

Each of the end plates 110A and 110B may be configured such that a metal insert is surrounded by a plastic injection-molded product. The metal insert of each of the end plates 110A and 110B may have high rigidity to withstand internal surface pressure and may be formed by machining a metal material. For example, each of the end plates 110A and 110B may be formed by combining a plurality of plates. However, the embodiments are not limited to any specific configuration of the end plates 110A and 110B.

The current collectors 112 may be disposed between the cell stack 122 and the inner surfaces 110AI and 110BI of the end plates 110A and 110B that face the cell stack 122. The current collectors 112 serve to collect the electrical energy generated by the flow of electrons in the cell stack 122 and to supply the electrical energy to a load that uses the fuel cell.

Further, the first end plate 110A may include a plurality of manifolds (or communicating portions) M. Each of the first and second separators 242 and 244 shown in FIG. 1 may include manifolds that are formed in the same shape at the same positions as the manifolds of the first end plate 110A. Here, the manifolds may include an inlet manifold and an outlet manifold. Hydrogen and oxygen, which are reactant gases necessary in the membrane electrode assembly 210, may be introduced from the outside into the cell stack 122 through the inlet manifold. Gas or liquid, in which the reactant gases humidified and supplied to the cell and the condensed water generated in the cell are combined, may be discharged to the outside of the fuel cell through the outlet manifold. The cooling medium may flow from the outside into the cell stack 122 through the inlet manifold and may flow from the cell stack 122 to the outside through the outlet manifold. As described above, the manifolds allow the fluid to flow into and out of the membrane electrode assembly 210.

In order to determine the performance and failure of the cell stack 122, the separators 242 and 244 of each cell may be connected to a control circuit via a cell monitoring device and a wire so as to measure the voltage of each cell. Here, the control circuit refers to a circuit including a measurement device and an electronic control unit for operating the fuel cell in a vehicle.

Hereinafter, the cell monitoring devices 100A and 100B according to embodiments, which check (or monitor) the state (e.g., voltage) of each of the unit cells included in the fuel cell, are described with reference to the accompanying drawings.

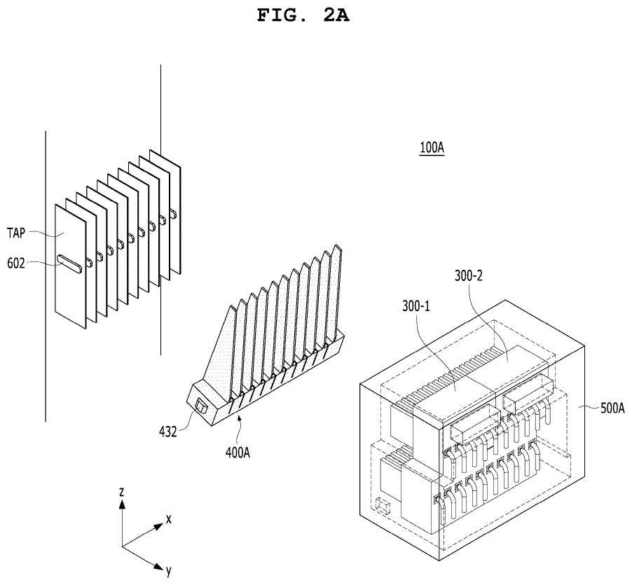

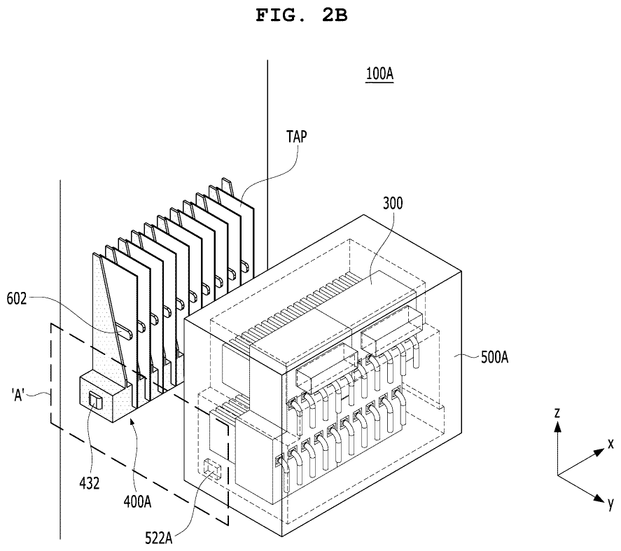

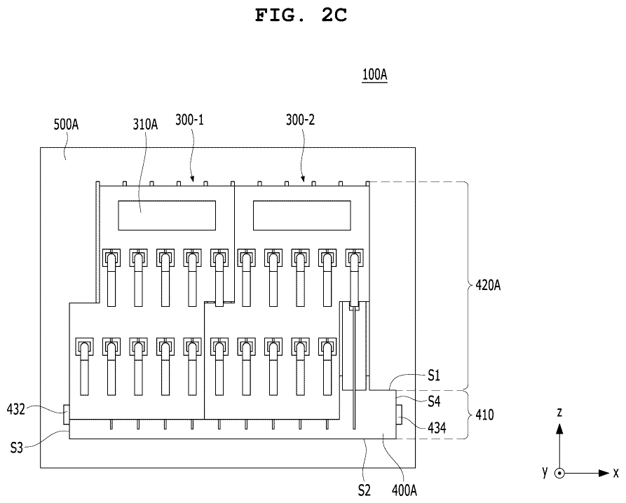

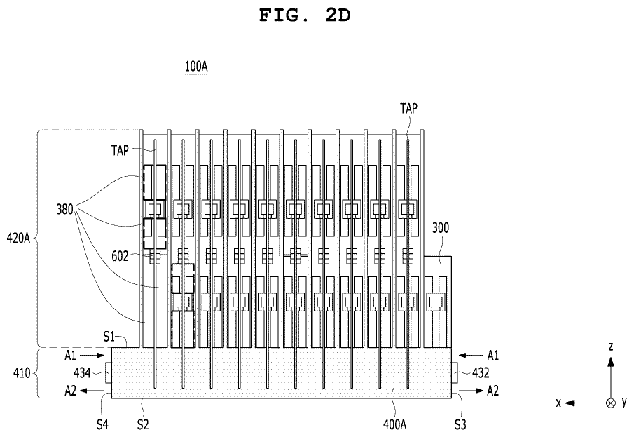

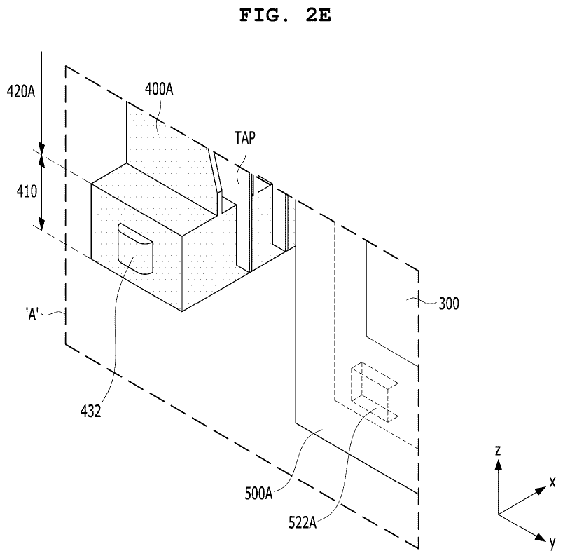

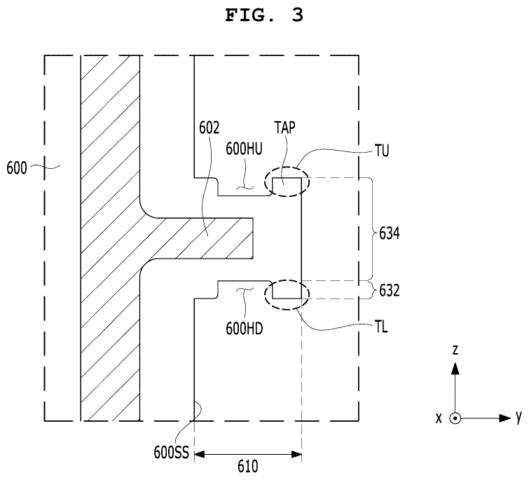

FIG. 2A is a partially assembled perspective view of a cell monitoring device 100A according to an embodiment. FIG. 2B is a further assembled perspective view of the cell monitoring device 100A shown in FIG. 2A. FIG. 2C is a front view of the cell monitoring device 100A shown in FIGS. 2A and 2B. FIG. 2D is a rear view of the cell monitoring device 100A shown in FIG. 2C. FIG. 2E is an enlarged perspective view of portion “A” shown in FIG. 2B. FIG. 3 is a side view of a separator 600 and a gasket 602 shown in FIGS. 2A-2D.

Illustration of a cover 500A is omitted in FIGS. 2C and 2D for better understanding.

For convenience of description, among the components of the fuel cell to which the cell monitoring device 100A according to the embodiment is mounted, only separators 600 and gaskets 602 are illustrated. The separators 600 and the gaskets 620 shown in FIG. 3, to which the cell monitoring device 100A according to an embodiment is connected, are merely given by way of example to aid in understanding the cell monitoring device 100A and may be implemented in any of various forms. Further, components of the fuel cell other than the separators 600 and the gaskets 602 may also be implemented in any of various forms. The embodiments are not limited to any specific configuration of the fuel cell.

In FIGS. 2A-2E, the part other than the separators 600 and the gaskets 602 corresponds to the cell monitoring device 100A according to an embodiment.

The separators 600 may correspond to the separators 242 and 244 shown in FIG. 1. The gaskets 602 may be airtight line gaskets and may correspond to the gaskets 232, 234, and 236 shown in FIG. 1. Alternatively, the gaskets 602 may be separate gaskets branching off from the gaskets 232, 234, and 236 shown in FIG. 1.

As the plurality of unit cells 122-1 to 122-N is stacked in the first direction, a plurality of separators 600 may be disposed so as to be spaced apart from each other in the first direction, as shown in FIGS. 2A, 2B, 2D, and 2E.

As shown in FIG. 3, each of the plurality of separators 600 may include a terminal 610 protruding from a side thereof in the second direction. Here, the second direction may be a direction protruding from a side 600SS of the separator 600 toward the cell monitoring device 100A. The cell monitoring device 100A may be coupled to a tab ‘TAP’ located at an end of the terminal 610.

The cell monitoring device 100A according to an embodiment may include a fuel cell monitoring connector or fuel stack voltage monitor (FSVM) (hereinafter referred to as a “connector”) 300 and a support part 400A. In addition, the cell monitoring device 100A according to the embodiment may further include a cover 500A.

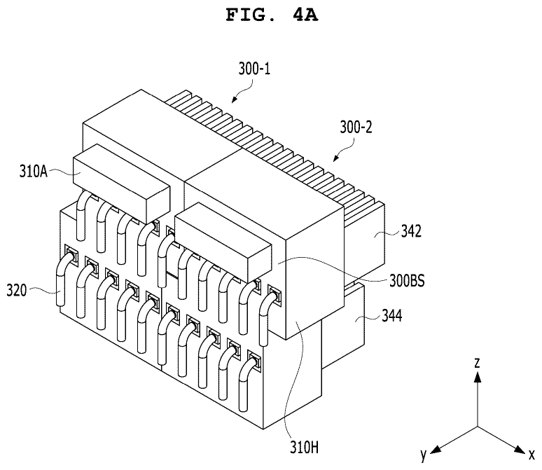

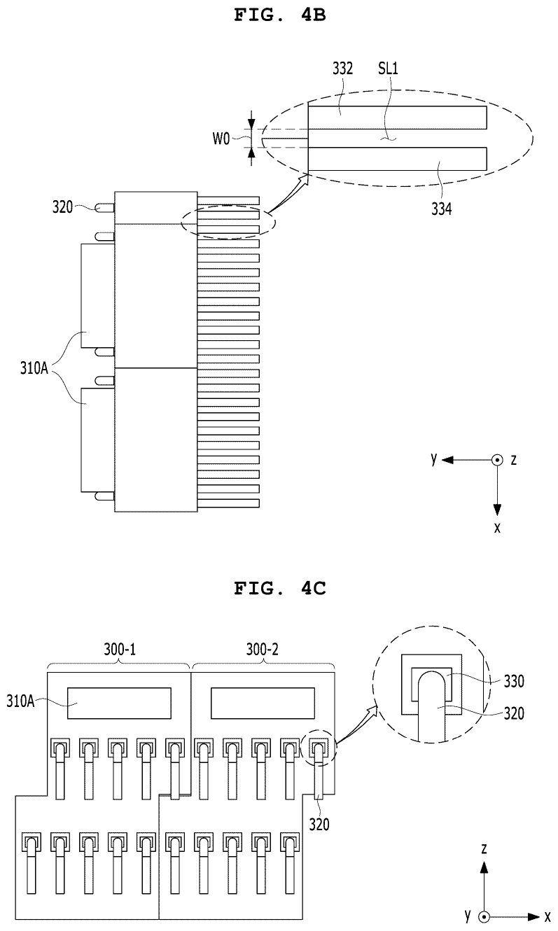

FIGS. 4A-4D are, respectively, a perspective view, a plan view, a front view, and a side view of two connectors 300 according to an embodiment.

The plurality of separators 600 included in the cell stack 122 may be some of all separators included in the fuel cell. For example, all of the separators included in the fuel cell may be grouped into unit groups, and each of the unit groups may include a plurality of separators 600. For example, FIGS. 2A-2E and FIGS. 4A-4D illustrate a plurality of separators 600 grouped into two unit groups. A first connector 300-1 may be mounted to the plurality of separators 600 belonging to the first unit group. A second connector 300-2 may be mounted to the plurality of separators 600 belonging to the second unit group. These cell monitoring connectors 300-1 and 300-2 may have the same configuration as each other and may perform the same operation as each other. For example, each of the unit groups shown in FIGS. 2A-2E may include five separators 600 and each of the unit groups shown in FIGS. 4A-4D may include ten separators 600. Each of the connectors 300-1 and 300-2 may be mounted to a respective one of the unit groups.

According to an embodiment, each of the connectors 300 (300-1 and 300-2) may include a first housing 310H, voltage sensing terminals, and wires 320.

The first housing 310H may include an upper slit portion 342 and a lower slit portion 344 formed in a front surface 300FS thereof and may include terminal insertion holes 330 and a connector coupling portion 310A formed in a rear surface 300BS thereof.

The connector coupling portion 310A is described below.

Each of the upper slit portion 342 and the lower slit portion 344 may include a plurality of first slits SL1. The first housing 310H may include partition walls 332, and each of the first slits SL1 may be located in a space between adjacent ones of the partition walls 332. The tabs TAP of the separators 600 may be fitted into the first slits SL1, as shown in FIG. 2D.

In addition, referring to FIGS. 4A-4D, the first housing 310H may include connection terminal insertion holes 330 formed in the rear surface thereof so as to communicate with the first slits SL1 formed in the front surface of the first housing 310H. The voltage sensing terminals and the wires 320 may be inserted into the connection terminal insertion holes 330.

In addition, the first housing 310H may include a groove ZA disposed between the first and second slit portions 342 and 344. Although not illustrated in the drawings, if the groove ZA is omitted, the first and second slit portions 342 and 344 may be formed separately from each other in the third direction. One of the first and second slit portions 342 and 344 may include first slits SL into which the terminals 610 of the odd-numbered (or even-numbered) separators among the plurality of separators 600 are fitted. The other of the first and second slit portions 342 and 344 may include first slits SL into which the terminals 610 of the even-numbered (or odd-numbered) separators among the plurality of separators 600 are fitted. As such, when adjacent ones of the separators 600 are alternately fitted into the slits SL of the two different slit portions 342 and 344, the sizes of gaps in the first direction between adjacent ones of the separators 600 may be reduced.

In addition, the gaskets 602 described above may be located in the space between the first and second slit portions 342 and 344.

In general, each of the separators 600 that are adjacent to each other is electrically conductive. The partition walls 332, which are electrically insulative, serve to electrically isolate the terminals 610 of the separators 600, which are fitted into the respective first slits SL, from each other. The occurrence of a short-circuit is thereby prevented between adjacent ones of the separators 600.

Further, the plurality of partition walls 332 may have the same thickness as each other in the first direction. The plurality of first slits SL may have the same width W0 as each other in the first direction.

The voltage sensing terminals 320 may be inserted into the connection terminal insertion holes 330 in the housing 310H and may be respectively connected to the terminals 610 of the plurality of separators 600.

An example of the voltage sensing terminals 320 corresponds to the connection terminals 320 disclosed in Korean Patent Registration No. 10-1337937 (Registered on Dec. 2, 2013 and titled “CONNECTOR FOR MEASURING CELL VOLTAGE OF FUEL CELL STACK”). Since the voltage sensing terminals are well known, detailed description thereof has been omitted.

According to an embodiment, the connector 300 may be coupled to the tabs TAP while being supported by the support part 400A. The support part 400A may be fitted and fixed to the tabs TAP protruding from the separators 600 included in each of the plurality of unit cells in the second direction intersecting the first direction.

Hereinafter, the support part 400A according to the embodiment is described with reference to the accompanying drawings.

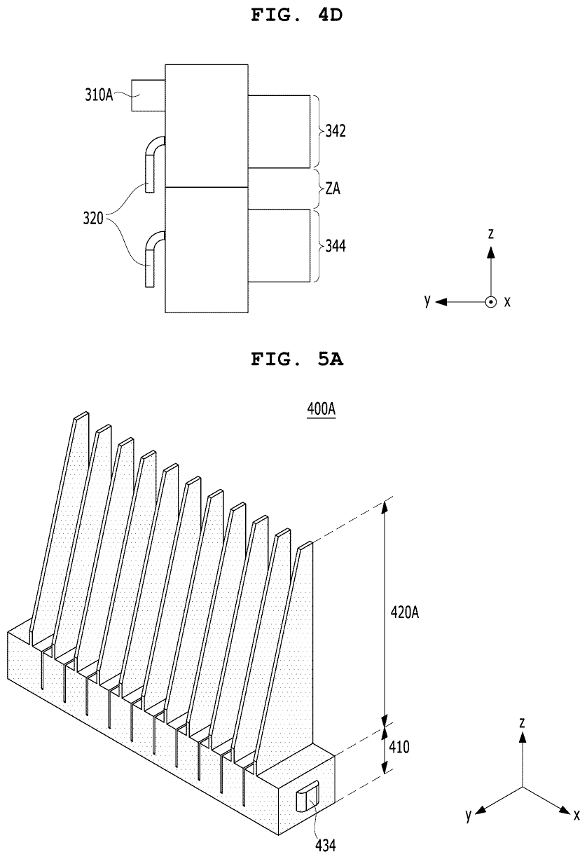

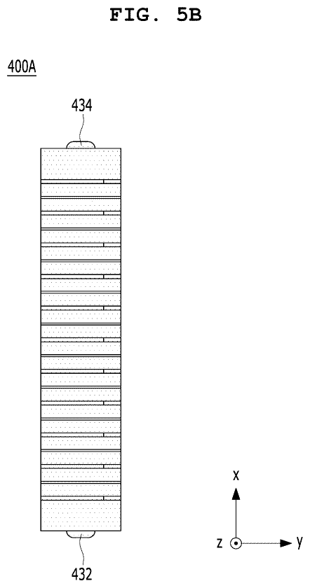

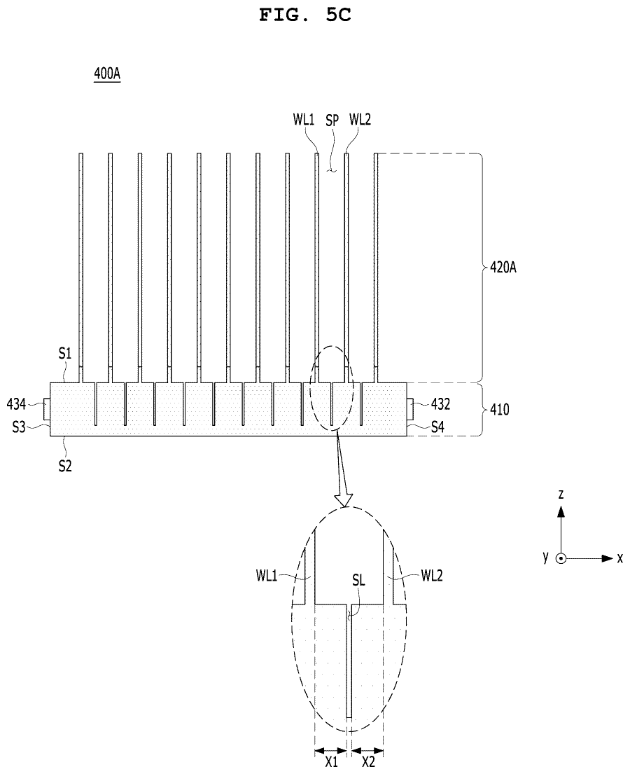

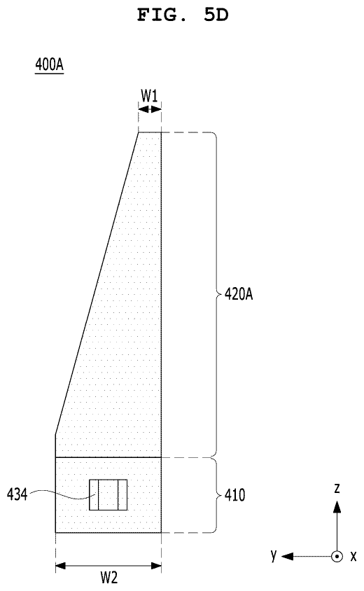

FIG. 5A is a perspective view of an embodiment of the support part 400A shown in FIG. 2A. FIG. 5B is a plan view of an embodiment of the support part 400A shown in FIG. 5A. FIG. 5C is a front view of an embodiment of the support part 400A shown in FIG. 5A. FIG. 5D is a side view of an embodiment of the support part 400A shown in FIG. 5A.

The support part 400A may include a body 410 and a plurality of partition walls 420A.

The body 410 may be fitted and fixed to a portion of an upper side TU or a lower side TL of the tab TAP shown in FIG. 3. For example, as illustrated in FIGS. 2A-2E, the body 410 may be fitted and fixed to a portion 632 of the lower side TL of the tab TAP.

The plurality of partition walls 420A may extend from the body 410 in the third direction intersecting each of the first direction and the second direction to define a space SP in which each of the other portions 634 of the tabs TAP is disposed. The plurality of partition walls 420A may be arranged in the first direction, which is identical to the first direction in which the separators 600 are arranged. The plurality of partition walls 420A may branch off from the single body 410 and may extend in the third direction.

For example, when it is intended to accommodate ten separators 600, the number of partition walls 420A may be eleven.

The body 410 may include first to fourth surfaces S1, S2, S3, and S4. The first surface S1 may be a surface in which a second slot SL2 is formed. Here, the second slot SL2 corresponds to a portion into which a portion of the lower side TL or the upper side TU of the tab TAP of the separator 600 (portion 632 of the lower side TL in the case of FIG. 3) is fitted. The second surface S2 corresponds to a surface located opposite the first surface S1 in the third direction.

According to an embodiment, as shown in the drawings, the first surface S1 may correspond to the top surface of the body 410 and the second surface S2 may correspond to the bottom surface of the body 410. Unlike what is illustrated in the drawings, the first surface S1 may instead correspond to the bottom surface of the body 410 and the second surface S2 may correspond to the top surface of the body 410.

The third surface S3 may be a surface located between the first surface S1 and the second surface S2 and the fourth surface S4 may be a surface located opposite the third surface S3 in the first direction.

In addition, according to an embodiment, the second slot SL2 may be located in the middle between two neighboring partition walls that define a space in which the other portion 634 of the tab TAP is disposed.

For example, referring to FIG. 5C, a first distance X1 between the first partition wall WL1 and the second slot SL2 disposed between two neighboring partition walls WL1 and WL2 may be identical to a second distance X2 between the second slot SL2 and the second partition wall WL2.

According to an embodiment, the width of each of the plurality of partition walls 420A in the second direction may gradually decrease with increasing distance from the body 410 in the third direction. For example, referring to FIG. 5D, a width W1 of a portion of the partition wall 420A in the second direction that is located farthest from the body 410 in the third direction may be the smallest width among the widths of the partition wall 420A in the second direction. Also, a width W2 of a portion of the partition wall 420A in the second direction that is located closest to the body 410 in the third direction may be the largest width among the widths of the partition wall 420A in the second direction. In this case, the second width W2 is larger than the first width W1.

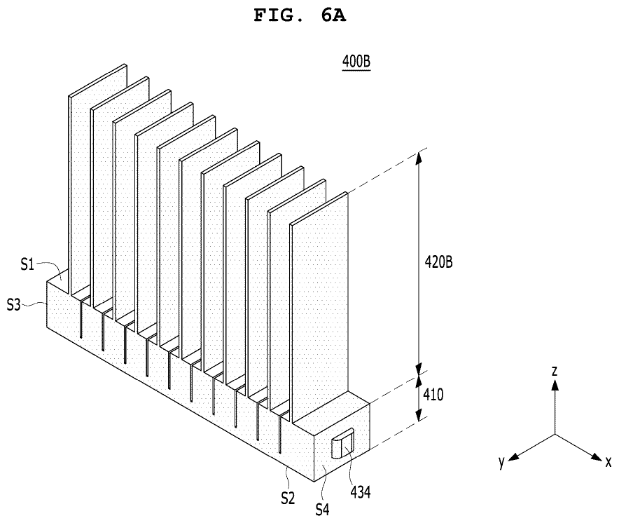

FIGS. 6A and 6B are, respectively, a perspective view and a side view of a support part 400B according to another embodiment.

According to another embodiment, the width of each of the plurality of partition walls 420B in the second direction may be constant. For example, referring to FIG. 6B, the width W2 of each of the plurality of partition walls 420B in the second direction may be constant, and may be identical to the width W2 of the body 410. In this case, the width of each of the plurality of partition walls 420A in the second direction may be constant but may be different from the width W2 of the body 410 in the second direction.

Since the support part 400B shown in FIGS. 6A and 6B is the same as the support part 400A shown in FIGS. 5A and 5D except that the widths of the partition walls 420A and 420B are different from each other, the same components are denoted by the same reference numerals and a duplicate description thereof has been omitted.

The support part 400A shown in FIGS. 2A-2E may be substituted with the support part 400B shown in FIGS. 6A and 6B.

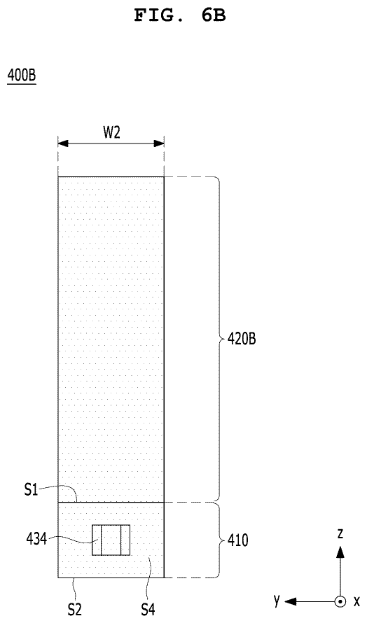

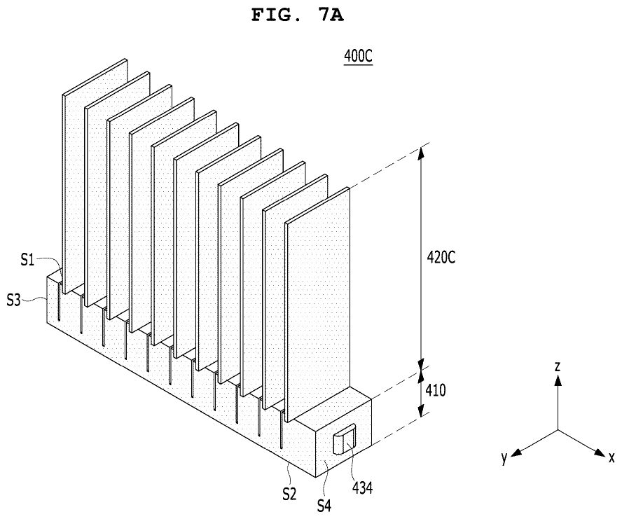

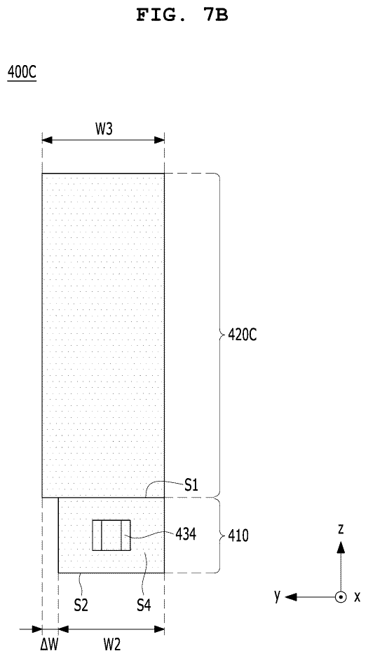

FIGS. 7A and 7B are, respectively, a perspective view and a side view of a support part 400C according to still another embodiment.

According to still another embodiment, each of the plurality of partition walls 420C may have a shape that further protrudes than the body 410 toward the connector 300 in the second direction. For example, referring to FIG. 7B, the plurality of partition walls 420C may have a constant width W3 in the second direction. Also, the width W3 may be larger than the width W2 of the body 410 in the second direction and may further protrude toward the connector 300 by a difference ΔW between the widths W2 and W3 of the plurality of partition walls 420C. Since the support part 400C shown in FIGS. 7A and 7B is the same as the support part 400B shown in FIGS. 6A and 6D except that the widths of the partition walls 420B and 420C are different from each other, the same components are denoted by the same reference numerals and a duplicate description thereof has been omitted.

The support part 400A shown in FIGS. 2A-2E may be substituted with the support part 400C shown in FIGS. 7A and 7B.

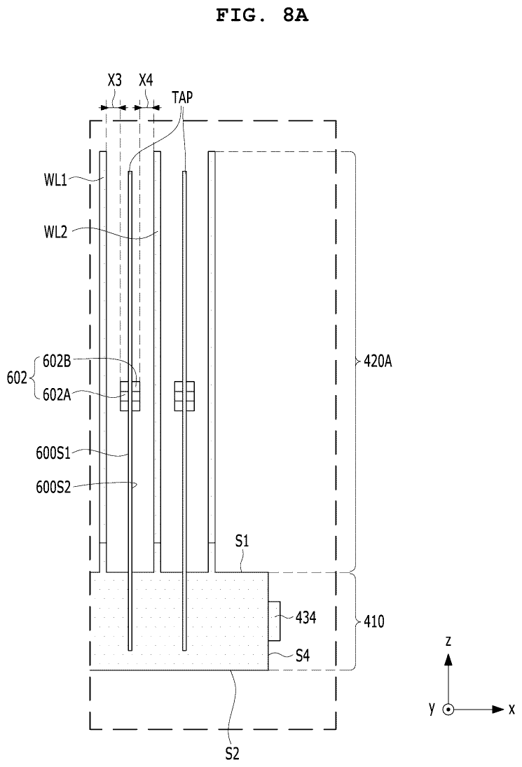

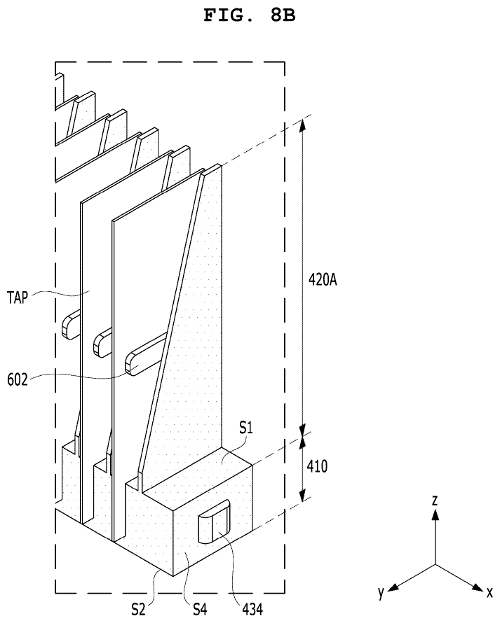

FIGS. 8A and 8B are, respectively, a partially coupled front view and a partial side perspective view of the tab TAP and the support part 400A shown in FIGS. 2A-2E.

Referring to FIG. 8A, the gasket 602 may protrude from each of both side surfaces 600S1 and 60052 of the tab TAP in the first direction and may be spaced apart from each of the plurality of partition walls WL1 and WL2. That is to say, the gasket 602A protruding from the first side surface 600S1 among both side surfaces 600S1 and 600S2 of the tab TAP may be spaced apart from the partition wall WL1 by a third distance X3. Also, the gasket 602B protruding from the second side surface 600S2 among both side surfaces 600S1 and 60052 of the tab TAP may be spaced apart from the partition wall WL2 by a fourth distance X4. Accordingly, the connector 300 may be reliably inserted between the tabs TAP of the separators 600 while being supported by the support part 400A.

Meanwhile, the cover 500A is disposed so as to surround the connector 300 and is coupled to and supported by the support part 400A, 400B, or 400C, thereby serving to fix the connector 300 fitted to the tabs TAP.

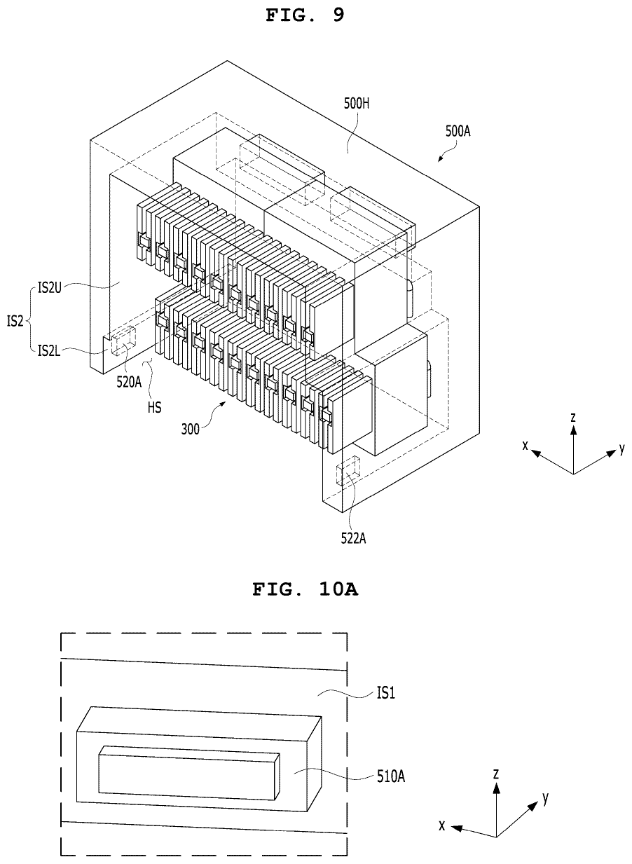

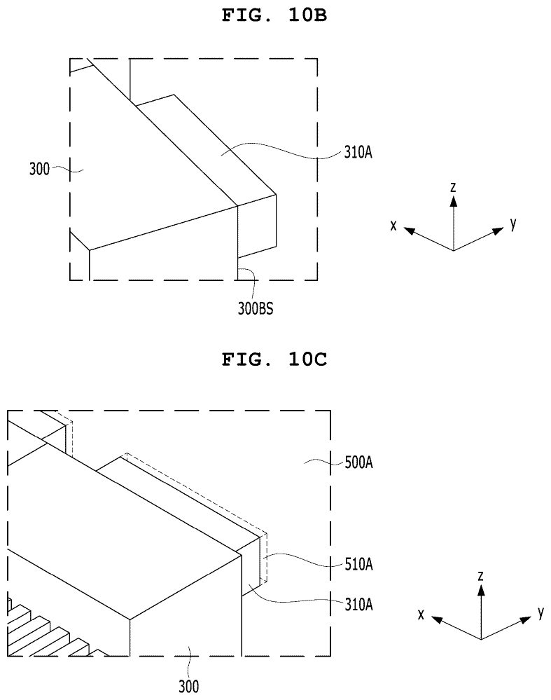

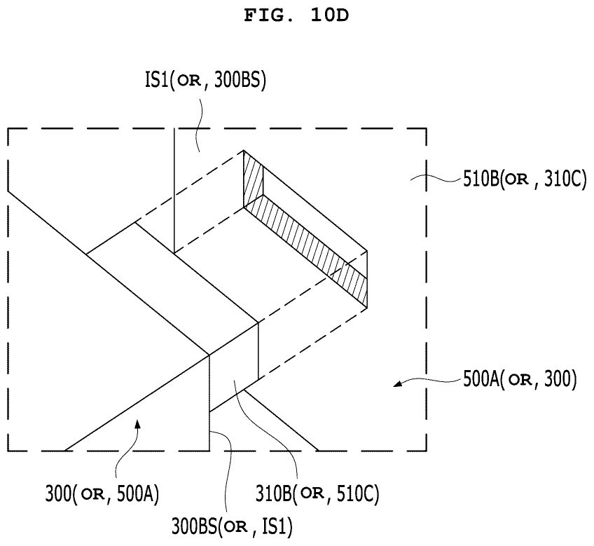

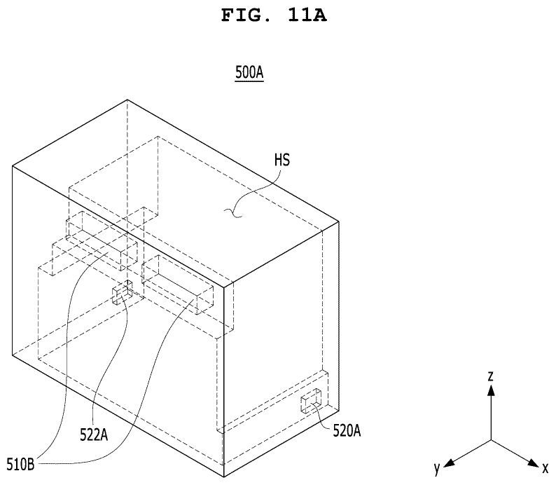

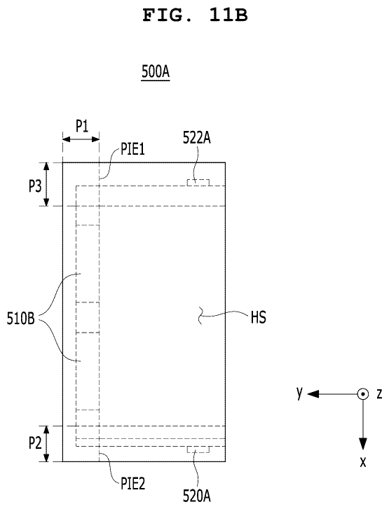

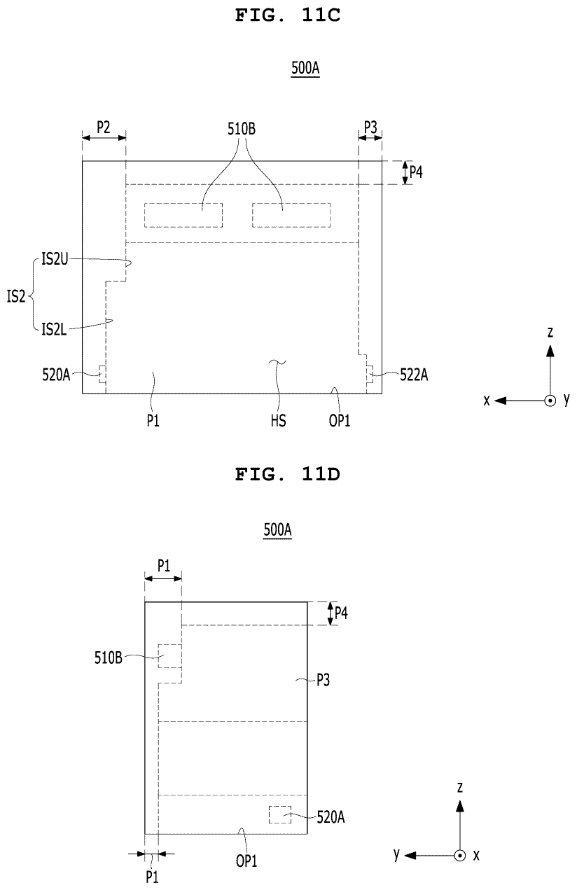

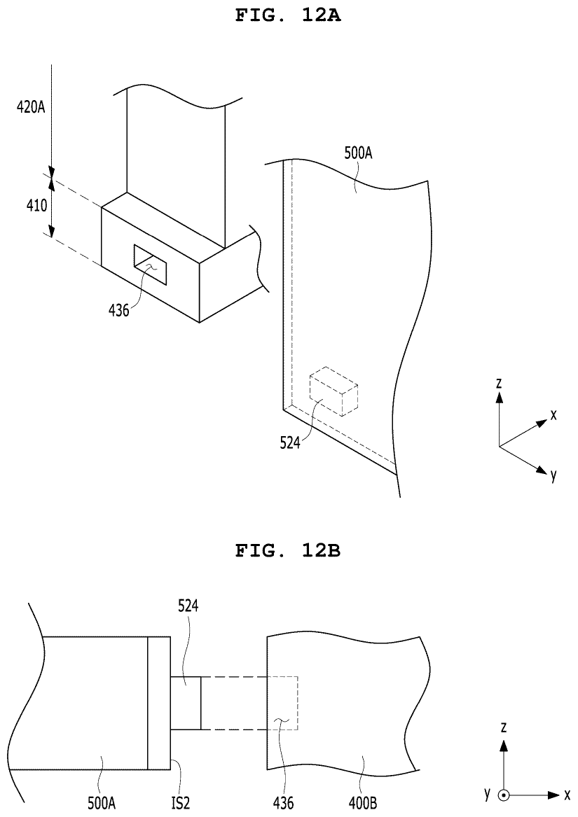

FIG. 9 is a coupled rear perspective view of embodiments of the connector 300 and the cover 500A shown in FIGS. 2A-2E. FIG. 10A is a partial perspective view of an embodiment of the cover 500A shown in FIGS. 2A-2E. FIG. 10B is a partial perspective view of an embodiment of the connector 300 shown in FIGS. 2A- to 2E. FIG. 10C is a partially coupled perspective view of embodiments of the connector 300 and the cover 500A shown in FIGS. 2A-2E. FIG. 10D is a partially exploded perspective view of other embodiments of the connector and the cover shown in FIGS. 2A-2E. FIGS. 11A-11D are, respectively, a perspective view, a plan view, a front view, and a side view of the cover 500A shown in FIGS. 2A-2E. FIGS. 12A and 12B are, respectively, an exploded perspective view and an exploded cross-sectional view of a support part and a cover according to another embodiment.

According to an embodiment, the connector 300 may be coupled to the tabs TAP of the separators 600 while being coupled to the cover 500A. To this end, according to an embodiment, the connector 300 may be coupled to the cover 500A in various forms, which is described below with reference to the accompanying drawings.

The cover 500A may include a second housing 500H and a first cover coupling portion.

The second housing 500H includes a receiving hole HS formed therein so as to receive the connector 300.

The first cover coupling portion may be disposed on a first inner side surface IS1 of the second housing 500H that faces the connector 300 in the second direction and may be coupled to the connector 300. In this case, the connector 300 may include a connector coupling portion that is coupled to the first cover coupling portion of the cover 500A in a fitting manner.

According to an embodiment, the first cover coupling portion and the connector coupling portion may be coupled to each other in various forms. Coupling therebetween is not limited to any specific coupling method.

According to an embodiment, as shown in FIGS. 10A-10C, the connector coupling portion may include a first protruding portion 310A and the first cover coupling portion may include a second protruding portion 510A.

The first protruding portion 310A protrudes from the rear surface 300BS of the connector 300 toward the first inner side surface IS1 of the second housing 500H. The second protruding portion 510A protrudes from the first inner side surface IS1 of the second housing 500H toward the rear surface 300BS of the connector 300. In this case, an end portion of the first protruding portion 310A and an end portion of the second protruding portion 510A may be coupled to each other in a fitting manner. For example, as shown in FIG. 10A, an end portion of the second protruding portion 510A may have a step. An end portion of the first protruding portion 310A may be coupled to the stepped end portion of the second protruding portion 510A in a fitting manner. Coupling between the first protruding portion 310A and the second protruding portion 510A is not limited to any specific coupling method, as long as the first protruding portion 310A is capable of being fitted into and engaged with the second protruding portion 510A when the connector 300 is pressed to the first inner side surface IS1 of the second housing 500H. The connectors 300 may be separated individually from the cover 500A due to the above-described coupling method.

According to another embodiment, as shown in FIG. 10D, the connector coupling portion includes a third protruding portion 310B and the first cover coupling portion includes a first concave portion 510B. The third protruding portion 310B protrudes from the rear surface 300BS of the connector 300 toward the first inner side surface IS1 of the second housing 500H. The first concave portion 510B is disposed on the first inner side surface IS1 of the second housing 500H to receive the third protruding portion 310B. In this case, the third protruding portion 310B may be received in the first concave portion 510B, whereby the connector 300 may be coupled to the cover 500A.

According to still another embodiment, as shown in FIG. 10D, the first cover coupling portion may include a fourth protruding portion 510C and the connector coupling portion may include a second concave portion 310C.

The fourth protruding portion 510C may be disposed on the first inner side surface IS1 of the second housing 500H and may protrude toward the rear surface 300BS of the connector 300. The second concave portion 310C may be disposed on the rear surface 300BS of the connector 300 and may receive the fourth protruding portion 510C. In this case, the fourth protruding portion 510C may be received in the second concave portion 310C, whereby the connector 300 may be coupled to the cover 500A.

Meanwhile, according to an embodiment, the cover 500A may be coupled to the support part 400A in a state in which the connector 300 is coupled to the cover 500A. To this end, according to embodiments, the support part 400A may be coupled to the cover 500A in various forms, which are described below with reference to the accompanying drawings.

The cover 500A may further include a second cover coupling portion. Referring to FIGS. 2E and 11C, the second cover coupling portion may be disposed on a second inner side surface IS2 of the second housing 500H that faces the support part 400A in the first direction and may be coupled to the support part 400A. In this case, the support part 400A may include a support part coupling portion that is coupled to the second cover coupling portion in a fitting manner.

According to an embodiment, the second cover coupling portion and the support part coupling portion may be coupled to each other in various forms. Coupling therebetween is not limited to any specific coupling method.

According to an embodiment, the support part coupling portion may include fifth protruding portions 432 and 434 and the second cover coupling portion may include third concave portions 520A and 522A.

The fifth protruding portions 432 and 434 are disposed on the outer sides of the third and fourth surfaces S3 and S4 of the body 410A, respectively, and protrude toward the second inner side surface IS2 of the second housing 500H. The third concave portions 520A and 520C disposed on the second inner side surface IS2 of the second housing 500H receive the fifth protruding portions 432 and 434. In this case, the fifth protruding portions 432 and 434 may be received in the third concave portions 520A and 520C, respectively, whereby the support part 400A and the cover 500A may be coupled to each other.

According to another embodiment, the support part coupling portion may include a fourth concave portion 436 and the second cover coupling portion may include a sixth protruding portion 524.

Referring to FIGS. 12A and 12B, the sixth protruding portion 524 is disposed on the second inner side surface IS2 of the second housing 500H. The fourth concave portion 436 is disposed on the outer side of each of the third and fourth surfaces S3 and S4 of the body 410A of the support part 400B that face the second inner side surface IS2 of the second housing 500H and receives the sixth protruding portion 524. In this case, the sixth protruding portion 524 may be received in the fourth concave portion 436, whereby the support part 400B may be coupled to the cover 500A.

When the cover 500A is pushed in the second direction so as to be coupled to the support part 400A, the fifth protruding portions 432 and 434 may be pushed in a direction indicted by a first arrow A1 by a pressing force of the cover 500A, as shown in FIG. 2D. Then, when the fifth protruding portions 432 and 434 become aligned with the third concave portions 520A and 522A, the pressing force may be released. Then the fifth protruding portions 432 and 434 may be restored in a direction indicated by a second arrow A2 and may be received in and engaged with the third concave portions 520A and 522A. The sixth protruding portion 524 and the fourth concave portion 436 shown in FIGS. 12A and 12B may also be implemented in the structure described above.

In addition, referring to FIG. 11C, the second inner side surface IS2 may be defined by the line of the connector 300 that is received in the cover 500A and the outer peripheral line of the support part 400A to which the cover 500A is coupled. The thickness of an upper second inner side surface IS2U in the first direction may be greater than the thickness of a lower second inner side surface IS2L in the first direction.

According to an embodiment, the second housing 500H may have various shapes.

According to an embodiment, the second housing 500H of the cover 500A may include first to fourth portions P1 to P4.

Referring to FIGS. 11A-11D, the first portion P1 is defined as a portion of the second housing 500H that faces the rear surface 300BS of the connector 300 in the second direction. The second portion P2 is defined as a portion that extends in the second direction from one side P1E1 of one of both ends of the first portion P1 toward the separator 600. The third portion P3 is defined as a portion that extends in the second direction from one side P1E2 of the other of both ends of the first portion P1 toward the separator 600 and is located opposite the second portion P2 in the first direction. The fourth portion P4 defines a receiving hole HS in which the connector 300 is received while being coupled to the first to third portions P1, P2, and P3. In this case, the fourth portion P4 may be disposed so as to face the upper side or the lower side of the connector 300 in the third direction. The first to third portions P1 to P3 form an opening OP1 through which a portion of the connector 300 that is supported by the support part 400A is exposed. In addition, an opening through which a portion of the connector 300 that is connected to the tab TAP is exposed is located in a portion opposite the first portion P1 in the second direction.

As shown in the drawings, when the body 410 of the support part 400A is fitted and fixed to the lower portion of the tab TAP, the fourth portion P4 is disposed so as to face the upper side of the connector 300 in the third direction. In this case, the opening OP1 is formed in the bottom of the cover 500A.

On the other hand, unlike what is illustrated in the drawings, when the body 410 of the support part 400A or 400B is fitted and fixed to the upper portion of the tab TAP, the fourth portion P4 may be disposed so as to face the lower side of the connector 300 in the third direction. In this case, the opening OP1 may be formed in the top of the cover 500A.

Depending on an eye level of an operator who will engage the connector 300 with the tab TAP or a direction in which the connector 300 will be engaged with the tab TAP, the body 410 may be fitted and fixed to the lower portion of the tab TAP or the body 410 may be fitted and fixed to the upper portion of the tab TAP.

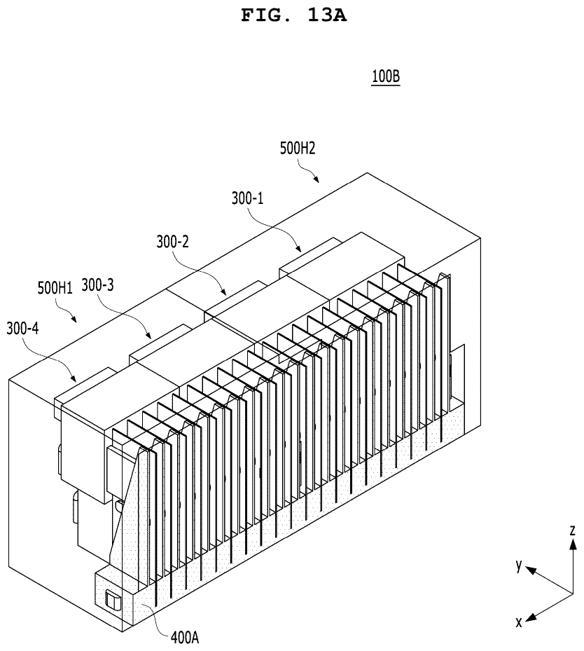

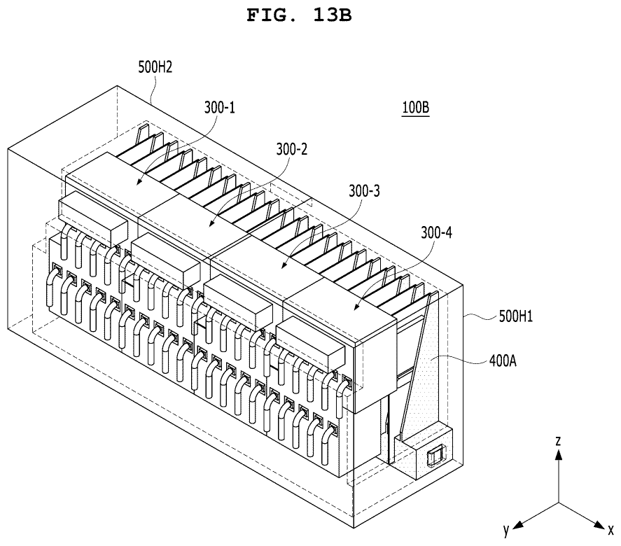

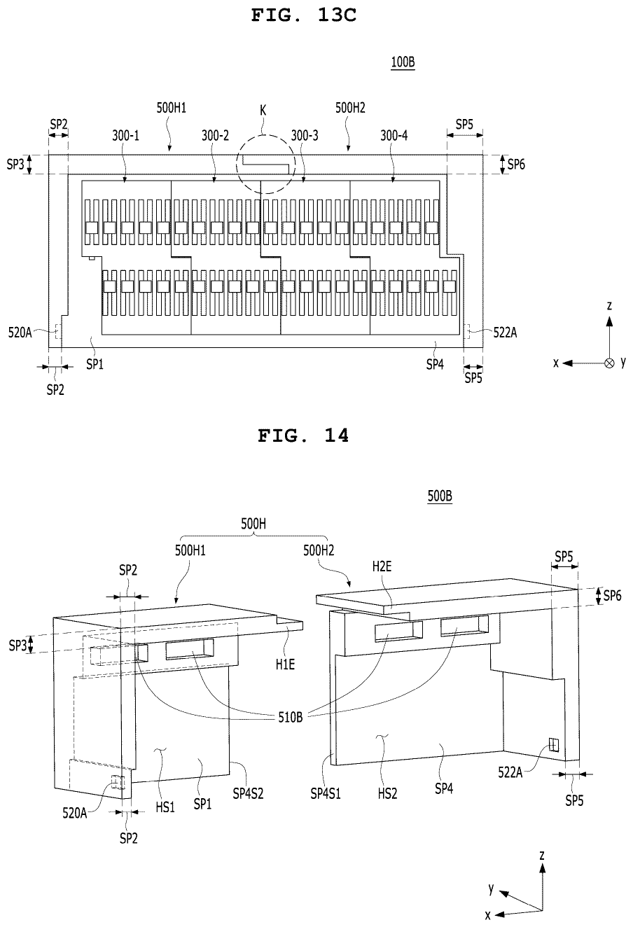

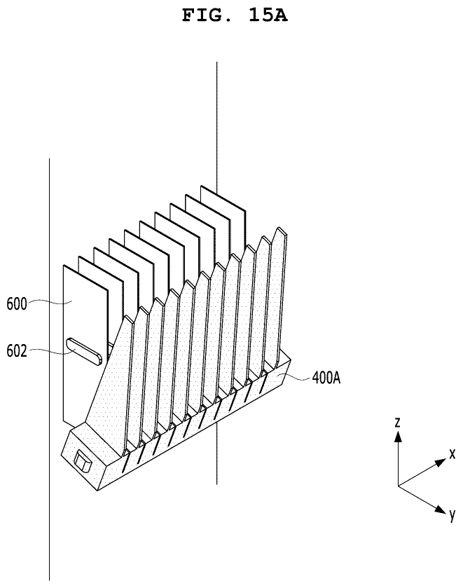

FIGS. 13A-13C are, respectively, a rear perspective view, a front perspective view, and a front view of a cell monitoring device 100B according to another embodiment. FIG. 14 is a perspective view of an embodiment of a cover 500B included in the cell monitoring device 100B shown in FIGS. 13A-13C.

The cell monitoring device 100B according to the other embodiment may include a plurality of connectors 300-1 to 300-4, a support part 400A, and a cover 500B.

Since the cell monitoring device 100B is the same as the cell monitoring device 100A described above except that the number of connectors 300 coupled to the cover 500B is four rather than two and the housing 500H has a different structure, the same components are denoted by the same reference numerals, and duplicate description thereof has been omitted.

Although it is illustrated that two connectors 300-1 and 300-2 are received in the cover 500A of the cell monitoring device 100A according to an embodiment and four connectors 300-1, 300-2, 300-3, and 300-4 are received in the cover 500B of the cell monitoring device 100B according to another embodiment, the embodiments are not limited to any specific number of connectors 300 received in the cover 500A or 500B. In other words, two to N/M connectors may be received in the cover 500A or 500B. Here, M represents the number of cells connected to one connector.

The second housing 500H may include first and second housings 500H1 and 500H2.

The first and second housings 500H1 and 500H2 may be coupled to each other in the first direction to define a receiving hole HS in which the connectors 300 (300-1 to 300-4) are received.

The first housing 500H1 may include first to third sub-portions SP1 to SP3 and the second housing 500H2 may include fourth to sixth sub-portions SP4 to SP6.

The first sub-portion SP1 is a portion that faces the rear surfaces of the connectors 300-1 and 300-2 in the second direction. The second sub-portion SP2 is a portion that extends in the second direction from one of both side portions of the first sub-portion SP1 toward the separator 600. The third sub-portion SP3 is coupled to the first sub-portion SP1 and the second sub-portion SP2 to define a space HS1 in which the first and second connectors 300-1 and 300-2 are received.

The fourth sub-portion SP4 is a portion that faces the rear surfaces of the connectors 300-3 and 300-4 in the second direction and includes a side portion contacting the other of both side portions of the first sub-portion SP1. The fifth sub-portion SP5 is a portion that extends in the second direction from the other of both side portions of the fourth sub-portion SP4 toward the separator 600 and faces the second sub-portion SP2 in the first direction. The sixth sub-portion SP6 is coupled to the fourth sub-portion SP4 and the fifth sub-portion SP5 to define a space HS2 in which the third and fourth connectors 300-3 and 300-4 are received.

An opening, through which portions of the first and second connectors 300-1 and 300-2 that are supported by the support part 400A are exposed, is formed in the first and second sub-portions SP1 and SP2. An opening, through which portions of the connectors 300-1 and 300-2 that are connected to the tabs TAP are exposed, is located in a portion opposite the first sub-portion SP1 in the second direction.

An opening, through which portions of the third and fourth connectors 300-3 and 300-4 that are supported by the support part 400A are exposed, is formed in the fourth and fifth sub-portions SP4 and SP5. An opening, through which portions of the connectors 300-3 and 300-4 that are connected to the tabs TAP are exposed, is located in a portion opposite the fourth sub-portion SP4 in the second direction.

According to an embodiment, an end portion of the third sub-portion SP3 and an end portion of the sixth sub-portion SP6 may be disposed so as to be interdigitated with, engaged with, or fitted to each other.

Hereinafter, a method of mounting the cell monitoring device 100A, according to an embodiment, to a fuel cell is described with reference to the accompanying drawings.

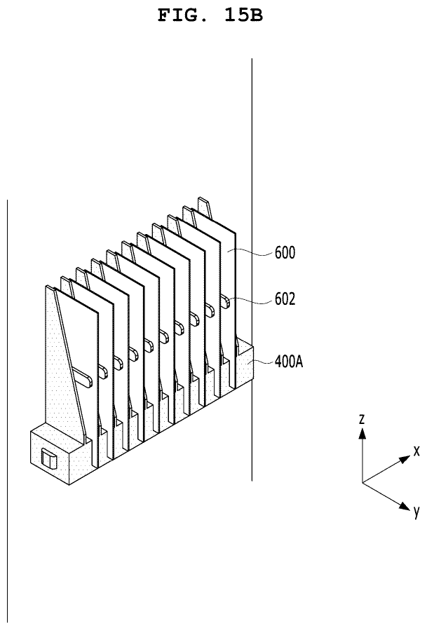

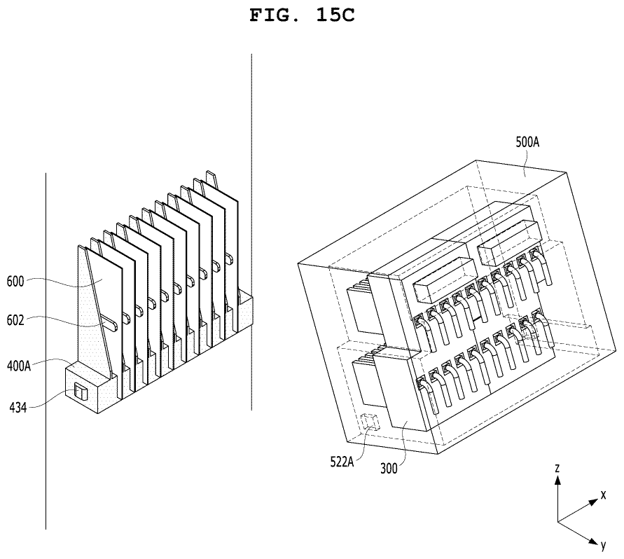

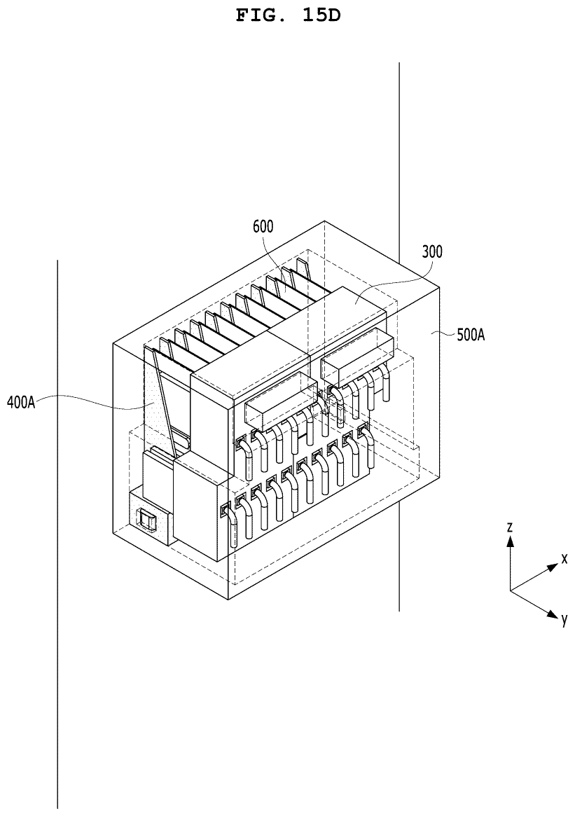

FIGS. 15A-15D are perspective views for explaining a method of mounting the cell monitoring device 100A for a fuel cell according to an embodiment.

Since the parts of the device shown in FIGS. 15A-15D are the same as the components of the device 100A according to the above-described embodiment, the same parts are denoted by the same reference numerals and a duplicate description thereof has been omitted.

First, as shown in FIG. 15A, the support part 400A is placed below the tabs TAP of the separators 600 and is moved upward so that the body 410 of the support part 400A is fitted to the tabs TAP. Thereby, as shown in FIG. 15B, the support part 400A is fitted and fixed to the lower ends of the tabs TAP of the separators 600. Accordingly, structural deformation of the tabs TAP of the separators 600 may be prevented.

Thereafter, as shown in FIG. 15C, in the state in which the connectors 300 are coupled to the cover 500A, the cover 500A is placed above the tabs TAP and is pushed downward so that the connectors 300 are fitted to the tabs TAP.

Thereafter, as shown in FIG. 15D, in the state in which the connectors 300 are supported by the support part 400A, the connectors 300 are pushed in the second direction toward the tabs TAP so that the support part 400A and the cover 500A are engaged with each other, whereby the device 100A may be mounted to the separators 600.

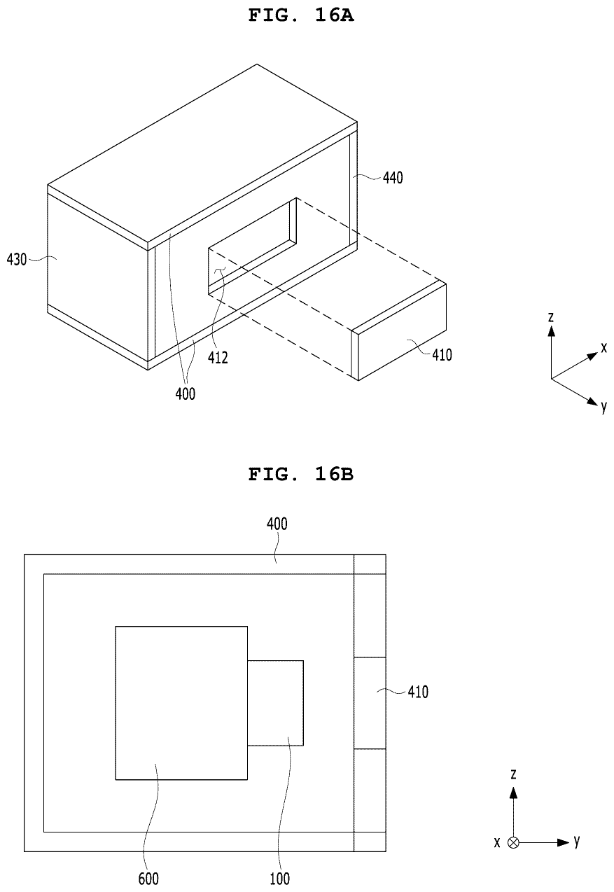

In this case, in the state in which an enclosure 400, which is described below with reference to FIGS. 16A and 16B, is not engaged, only the support part 400A may be engaged with the tabs TAP, as shown in FIG. 15B. Thereafter, the enclosure 400 may be engaged with the side cover 440 and the manifold block 430. Then the cover 500A may be engaged with the separators 600, as shown in FIGS. 15C and 15D.

FIGS. 16A and 16B are, respectively, a perspective view and a side-sectional view of the fuel cell and the cell monitoring device according to the embodiment.

The fuel cell may include a cell stack 600, an enclosure 400, an enclosure cover 410, a manifold block 430, and a side cover 440.

The enclosure 400 is disposed so as to be coupled to the manifold block 430 and the side cover 440 and to surround the cell stack 600. The manifold block 430 serves to evenly distribute oxygen, hydrogen, or coolant to the cell stack 600.

In some cases, the enclosure cover 410 may be separated from the enclosure 400 and the cell monitoring device 100 may be connected to the cell stack 600 exposed through the opening 412. Here, the cell monitoring device 100 may correspond to the cell monitoring devices 100A and 100B described above.

Alternatively, the cell monitoring device 100 according to an embodiment may be coupled to the fuel cell, which is the cell stack 600, in the enclosure 400.

Hereinafter, a cell monitoring device for a fuel cell according to a comparative example and the cell monitoring device according to the present disclosure are described based on a comparison therebetween.

An example of a cell monitoring device according to a comparative example is disclosed in Korean Patent Registration No. 10-1337937 (Registered on Dec. 2, 2013 and titled “CONNECTOR FOR MEASURING CELL VOLTAGE OF FUEL CELL STACK”).

In the case of the cell monitoring device according to the comparative example, connectors 100 are individually coupled to separators 10. In this case, the separators 10 may be easily bent or deformed by external pressure. In a stack in a unit module state after stacking of unit cells, there is no external housing or support structure protecting tab portions of the separator. Thus, the separators may be easily bent or deformed by small external force due to characteristics of material and thickness of the separators. In addition, a separate process for restoring the shape of the tabs of the deformed separators 10 may be additionally performed during assembly in order to achieve engagement with the connectors 100.

In addition, due to the characteristics of the cell stack that generates electric power using a structure in which hundreds of unit cells are stacked, the need for improvement of assemblability increases as the number of cells increases. In addition, in order to maintain a pin map, it is necessary to assemble the connectors in numerical order of the connectors. Therefore, it is impossible for an operator to intuitively assemble the connectors.

In addition, connector position assurances (CPAs) 140 are applied to upper ends of the connectors 100 in order to fix the position of the connectors 100 and to prevent separation of the connectors 100 in a state of fitting the connectors 100 to the separators 10. However, the connector position assurances (CPAs) need to be individually pushed in order to be engaged with the upper ends of the connectors. In some cases, it may not be easy to visually check the connector position assurances (CPAs) 140 depending on the stack assembly order or the position of the field of view of an assembler.

In contrast, according to the embodiments of the present disclosure, before the connectors 300 are coupled to the tabs TAP of the separators, the support part 400A or 400B is coupled to the separators 600 to align the tabs TAP. Therefore, the alignment of the separators 600 and the intervals between the cells, i.e., the cell pitch, are maintained. Accordingly, when the connectors 300 are coupled to the separators 600, the separators 600 may be prevented from being easily bent or deformed by external pressure, whereby the structural stability of the cell stack may be ensured. In addition, the support part 400A or 400B may support all of the plurality of cells through one surface of the body 410. In addition, the position of each of the tabs of the plurality of separators may be fixed by the partition walls 420A, 420B, or 420C.

In addition, according to the embodiments of the present disclosure, since the connector 300 is engaged with the cover 500A or 500B and the cover 500A or 500B is engaged with the support part 400A, 400B, or 400C, CPAS for fixing the connectors 300 to the tabs TAP are not needed.

According to the embodiments of the present disclosure, the plurality of connectors 300 is first coupled to the cover 500A or 500B and then is simultaneously coupled to the separators 600. Accordingly, compared to a case in which the connectors 300 are individually coupled to the separators 600, an assembly time may be shortened, and consequently, assemblability and productivity may be improved. In addition, since the connectors 300 are covered by the cover 500A or 500B, it may be possible to minimize interference with corresponding parts when assembling the enclosure 400 to the side cover 440 and the manifold block 430, as shown in FIG. 16B.

In general, when a fuel cell is used in a vehicle, a collision protection beam is provided in the fuel cell in order to protect a single module and ensure stability against low-speed collision. On the other hand, according to the embodiments of the present disclosure, when the cell monitoring device 100 is disposed as shown in FIG. 16B, the cell monitoring device 100 may also serve as a collision protection beam. Accordingly, it may be possible to ensure stack structure stability against low-speed collision at the single module without the necessity to mount a collision protection beam.

In addition, according to the embodiments of the present disclosure, since the connectors 300 are capable of being individually separated from the cover 500A or 500B, it may be possible to easily replace the connectors 300 during an after-sales service.

In this case, the body 410A of the support part 400A, 400B, or 400C is fitted and fixed to the tabs TAP of the separators 600, and the connectors 300 are also tightly fitted to and fixedly supported by the tabs TAP of the separators 600. That is to say, referring to FIG. 2D, the connectors 300 include portions 380 supporting the tabs TAP. Therefore, separate coupling parts are not needed between the support part 400A, 400B, or 400C and the connectors 300.

In addition, the width of the partition walls 420A, 420B, or 420C in the second direction may be set to various values within a range within which there is no interference between the connectors 300 and the cover 500A or 500B.

For example, when the width of the partition wall 420B is set as shown in FIGS. 6A and 6B, the entire area of the tab TAP is shielded by the partition wall 420B. Thus, it is possible to easily prevent the tab TAP from being deformed.

In addition, when the width of the partition wall 420C is set as shown in FIGS. 7A and 7B, the connectors 300 are fitted to the tabs TAP only through contact surfaces between the connectors 300 and the support part 400C. Thus, it is possible to regulate the insertion position and insertion length of the connectors 300.

In addition, as shown in FIGS. 13A-13C, when the cover 500B is implemented by connecting the plurality of second housings 500H1 and 500H2 in the cell stacking direction, an alignment maintaining structure (portion indicated by “K” in FIG. 13C) is applied to the surfaces of the neighboring second housings 500H1 and 500H2 that contact each other in order to align the second housings 500H1 and 500H2 with each other. Aligned connection between adjacent cover structures is thereby ensured. In this case, the third concave portions 520A and 522A are provided only in the second and fifth sub-portions SP2 and SP5 shown in FIG. 13C, whereby constant intervals may be maintained between adjacent cells included in the connectors 300-2 and 300-3. Consequently, matching interference between the adjacent connectors 300-2 and 300-3 may be prevented.

As should be apparent from the above description, according to the cell monitoring device for a fuel cell according to the embodiments of the present disclosure, separators may be prevented from being easily bent or deformed by external pressure, whereby the structural stability of a cell stack may be ensured. In addition, CPAs for fixing connectors to tabs are not needed. Thus, it may be possible to minimize interference with corresponding parts when assembling an enclosure to a side cover and a manifold block. In addition, it may be possible to ensure stack structure stability against low-speed collision at a single module without the necessity to mount a collision protection beam.

However, the effects achievable through the disclosed embodiments are not limited to the above-mentioned effects. Other effects not mentioned herein should be more clearly understood by those of ordinary skill in the art from the above description.

The above-described various embodiments may be combined with each other without departing from the scope of the present disclosure unless they are incompatible with each other.

In addition, for any element or process that is not described in detail in any of the various embodiments, reference may be made to the description of an element or a process having the same reference numeral in another embodiment, unless otherwise specified.

While the present disclosure has been particularly shown and described with reference to embodiments thereof, these embodiments are only proposed for illustrative purposes. These embodiments do not restrict the present disclosure. It should be apparent to those of ordinary skill in the art that various changes in form and detail may be made without departing from the essential characteristics of the embodiments set forth herein. For example, respective configurations set forth in the embodiments may be modified and applied. Further, differences in such modifications and applications should be construed as falling within the scope of the present disclosure as defined by the appended claims.

What is claimed is:

1. A cell monitoring device for a fuel cell, the cell monitoring device being configured to be mounted to a plurality of unit cells stacked in a first direction, the cell monitoring device comprising:
a support part configured to be fitted and fixed to tabs protruding in a second direction, intersecting the first direction, from separators included in each of the plurality of unit cells; and
a connector configured to be coupled to the tabs while being supported by the support part,
wherein the support part includes
a body configured to be fitted and fixed to portions of upper sides or lower sides of the tabs, and
a plurality of partition walls extending from the body in a third direction, intersecting each of the first and second directions, to define spaces in which other portions of the tabs are disposed, the plurality of partition walls being arranged in a same direction as a direction in which the separators are arranged.

2. The cell monitoring device according to claim 1, wherein a width of each of the plurality of partition walls in the second direction gradually decreases with increasing distance from the body in the third direction.

3. The cell monitoring device according to claim 1, wherein a width of each of the plurality of partition walls in the second direction is constant.

4. The cell monitoring device according to claim 1, wherein each of the plurality of partition walls has a shape further protruding than the body toward the connector in the second direction.

5. The cell monitoring device according to claim 1, further comprising a cover disposed so as to surround the connector and coupled to the support part to fix the connector fitted to the tabs.

6. The cell monitoring device according to claim 5, wherein the cover comprises:
a housing including a receiving hole formed therein so as to receive the connector;
a first cover coupling portion disposed on a first inner side surface of the housing facing the tabs in the second direction to be coupled to the connector; and
a second cover coupling portion disposed on a second inner side surface of the housing facing the support part in the first direction to be coupled to the support part.

7. The cell monitoring device according to claim 6, wherein the connector includes a connector coupling portion coupled to the first cover coupling portion in a fitting manner.

8. The cell monitoring device according to claim 7, wherein:
the connector coupling portion includes a first protruding portion protruding from a rear surface of the connector toward the first inner side surface of the housing;
the first cover coupling portion includes a second protruding portion protruding from the first inner side surface of the housing toward the rear surface of the connector; and
an end portion of the first protruding portion and an end portion of the second protruding portion are coupled to each other in a fitting manner.

9. The cell monitoring device according to claim 7, wherein:
the connector coupling portion includes a third protruding portion protruding from a rear surface of the connector toward the first inner side surface of the housing; and
the first cover coupling portion includes a first concave portion disposed on the first inner side surface of the housing to receive the third protruding portion.

10. The cell monitoring device according to claim 7, wherein:
the first cover coupling portion includes a fourth protruding portion disposed on the first inner side surface of the housing and protruding toward a rear surface of the connector; and
wherein the connector coupling portion includes a second concave portion disposed on the rear surface of the connector to receive the fourth protruding portion.

11. The cell monitoring device according to claim 6, wherein the support part includes a support part coupling portion coupled to the second cover coupling portion to be pressed-fit into.

12. The cell monitoring device according to claim 11, wherein:
the support part coupling portion includes a fifth protruding portion protruding toward the second inner side surface of the housing; and
the second cover coupling portion includes a third concave portion receiving the fifth protruding portion.

13. The cell monitoring device according to claim 11, wherein:
the second cover coupling portion includes a sixth protruding portion disposed on the second inner side surface of the housing; and
the support part coupling portion includes a fourth concave portion receiving the sixth protruding portion.

14. The cell monitoring device according to claim 11, wherein the body includes:
a first surface including slots formed therein so as to allow portions of the tabs to be fitted thereinto;
a second surface located opposite the first surface in the third direction;
a third surface located between the first surface and the second surface; and
a fourth surface located opposite the third surface in the first direction,
wherein the support part coupling portion is disposed on an outer side of each of the third and fourth surfaces of the body.

15. The cell monitoring device according to claim 14, wherein:
the first surface corresponds to a top surface of the body and the second surface corresponds to a bottom surface of the body; or
the first surface corresponds to a bottom surface of the body and the second surface corresponds to a top surface of the body.

16. The cell monitoring device according to claim 14, wherein each of the slots is located in the middle between two neighboring ones of the plurality of partition walls defining the spaces.

17. The cell monitoring device according to claim 1, further comprising a gasket protruding from each of both surfaces of each of the tabs in the first direction and spaced apart from each of the plurality of partition walls.

18. The cell monitoring device according to claim 6, wherein the housing of the cover includes:
a first portion facing a rear surface of the connector in the second direction;
a second portion extending in the second direction from one side of one of two ends of the first portion toward the separators;
a third portion extending in the second direction from one side of a remaining one of the two ends of the first portion toward the separators and located opposite the second portion in the first direction; and
a fourth portion coupled to the first, second, and third portions to define the receiving hole and disposed so as to face an upper side or a lower side of the connector in the third direction,
wherein the first, second, and third portions form an opening to expose a portion of the connector supported by the support part.

19. The cell monitoring device according to claim 1, wherein the cell monitoring device is disposed in an enclosure included in the fuel cell.
